(19) United States
(12) Patent Application Publication
(10) Pub. No.: US 2025/0331404 A1
(43) Pub. Date: Oct. 23, 2025

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Xilei CAO, Beijing (CN); Zhenhua ZHANG, Beijing (CN); Wulin SHEN, Beijing (CN); Jianmin YE, Beijing (CN); Tong WU, Beijing (CN); Baolei HUO, Beijing (CN)

(21) Appl. No.: 18/861,844

(22) PCT Filed: Jan. 2, 2024
(86) PCT No.: PCT/CN2024/070150

§ 371 Date: Oct. 30, 2024

(30) Foreign Application Priority Data
Jan. 13, 2023 (CN) 202310077452.9

(51) Int. Cl. H10K 59/80

(52) U.S. Cl. CPC H10K 59/879; H10K 59/80515

(57) ABSTRACT

Provided is a display panel, including: a base substrate; a light-emitting layer, disposed on the base substrate, wherein the light-emitting layer comprises a plurality of effective light-emitting regions; a first electrode pattern, disposed on the base substrate where the light-emitting layer is disposed, wherein the first electrode pattern comprises a plurality of opening regions, an orthographic projection of each of the plurality of opening regions on the base substrate being between orthographic projections of the plurality of effective light-emitting regions on the base substrate; and a plurality of first efficiency enhancement structures, disposed on the base substrate where the first electrode pattern is disposed, wherein orthographic projections of the plurality of first efficiency enhancement structures on the first electrode pattern are overlapped with the opening regions, each of the plurality of first efficiency enhancement structures comprises a first light transmitting layer and a second light transmitting layer.

### CROSS-REFERENCE TO RELATED APPLICATION

The present disclosure is a U.S. national phase application based on PCT/CN2024/070150, filed on Jan. 2, 2024, which claims priority to Chinese Patent Application No. 202310077452.9, filed on Jan. 13, 2023, and entitled “DISPLAY PANEL AND DISPLAY DEVICE,” the contents of which are incorporated herein by reference in their entireties.

### TECHNICAL FIELD

Embodiments of the present disclosure relate to the field of display technologies, and in particular, relate to a display panel and a display device.

### BACKGROUND

A display panel is a device for displaying images. The display panel includes a base substrate, a plurality of light-emitting elements disposed on the base substrate, and some circuit structures for driving the light-emitting elements. These circuit structures are capable of driving the light-emitting elements to emit light to implement an image display function.

### SUMMARY

Embodiments of the present disclosure provide a display panel and a display device. The technical solutions are as follows.

According to some embodiments of the present disclosure, a display panel is provided. The display panel includes:
a base substrate;
a light-emitting layer, disposed on the base substrate, wherein the light-emitting layer includes a plurality of effective light-emitting regions;
a first electrode pattern, disposed on a base substrate where the light-emitting layer is disposed, wherein the first electrode pattern includes a plurality of opening regions, orthographic projections of the plurality of opening regions on the base substrate are between orthographic projections of the plurality of effective light-emitting regions on the base substrate; and
a plurality of first efficiency enhancement structures, disposed on the base substrate where the first electrode pattern is disposed, wherein orthographic projections of the first efficiency enhancement structures on the first electrode pattern is overlapped with the opening regions, each of the plurality of first efficiency enhancement structures includes a first light transmitting layer and a second light transmitting layer, the first light transmitting layer and the second light transmitting layer are sequentially laminated on the base substrate where the first electrode pattern is disposed, a protrusion structure is disposed on one of the first light transmitting layer and the second light transmitting layer towards the other of the first light transmitting layer and the second light transmitting layer, and a refractive index of the first light transmitting layer is less than a refractive index of the second light transmitting layer.

In some embodiments, the display panel further includes a second electrode pattern, wherein the second electrode pattern is disposed between the base substrate and the light-emitting layer, the second electrode pattern includes a plurality of second electrodes, and orthographic projections of the plurality of opening regions on the second electrode pattern are between the plurality of second electrodes.

In some embodiments, the display panel further includes a plurality of thin film transistors, wherein the plurality of thin film transistors are disposed between the second electrode pattern and the base substrate, and the orthographic projection of each of the plurality of opening regions on the base substrate is between orthographic projections of the plurality of thin film transistors on the base substrate.

In some embodiments, a first hole is defined in the first light transmitting layer, an orthographic projection of the first hole on the base substrate is overlapped with the orthographic projection of each of the plurality of opening regions of the first electrode pattern on the base substrate; and
a first protrusion structure is disposed on the second light transmitting layer towards the base substrate, wherein the first protrusion structure is filled in the first hole.

In some embodiments, the display panel further includes a plurality of second efficiency enhancement structures, wherein the second efficiency enhancement structures include a third light transmitting layer and a fourth light transmitting layer, and the third light transmitting layer and the fourth light transmitting layer are sequentially laminated on the base substrate where the first electrode pattern is disposed; and
a second hole is defined in the third light transmitting layer, an orthographic projection of the second hole on the base substrate is overlapped with the orthographic projections of the effective light-emitting region on the base substrate, and a second protrusion structure is disposed on the fourth light transmitting layer towards the third light transmitting layer, wherein the second protrusion structure is filled in the second hole.

In some embodiments, dimensions of the second hole and the first hole both increase in a direction away from the base substrate, and a slope angle of a hole wall of the first hole is greater than a slope angle of a hole wall of the second hole.

In some embodiments, the orthographic projection of the effective light-emitting region on the base substrate is within the orthographic projection of the second hole on the base substrate, and a first distance is defined between an edge of the orthographic projection of the effective light-emitting region on the base substrate and an edge of the orthographic projection of the second hole on the base substrate; and
the orthographic projection of the opening region of the first electrode pattern on the base substrate is within the orthographic projection of the first hole on the base substrate, and a second distance is defined between an edge of the orthographic projection of the opening region on the base substrate and an edge of the orthographic projection of the first hole on the base substrate, and the second distance is greater than the first distance.

In some embodiments, a thickness of the third light transmitting layer is greater than a thickness of the first light transmitting layer.

In some embodiments, the first light transmitting layers in the plurality of first efficiency enhancement structures are disposed in a same layer, and the second light transmitting layers in the plurality of first efficiency enhancement structures are disposed in a same layer; and
the first light transmitting layer and the third light transmitting layer are disposed in a same layer, and the second light transmitting layer and the fourth light transmitting layer are disposed in a same layer.

In some embodiments, a recess is defined in the first light transmitting layer, and an orthographic projection of the recess on the base substrate is overlapped with the orthographic projection of the opening region of the first electrode pattern on the base substrate; and
a third protrusion structure is disposed on the second light transmitting layer towards the second light transmitting layer, and the third protrusion structure is filled in the recess.

In some embodiments, the orthographic projection of the opening region of the first electrode pattern on the base substrate is within an orthographic projection of the recess on the base substrate.

In some embodiments, the recess is an arc-shaped recess and a center of the arc-shaped recess is outside the recess.

In some embodiments, at least two protrusion structures are disposed on the first light transmitting layer.

In some embodiments, the protrusion structure includes a base and an arc-shaped protrusion disposed on the base, a center of the arc-shaped protrusion is disposed on a side, away from the base substrate, of a center of the protrusion structure, and the center of the protrusion structure is a center of the protrusion structures in a direction perpendicular to the base substrate.

In some embodiments, the first electrode pattern is a cathode pattern;
the display panel includes a plurality of light transmitting structures, disposed on the base substrate provided with the light-emitting layer, a material of the light transmitting structures includes a cathode patterning material; and
the first electrode pattern is disposed on the base substrate where the plurality of light transmitting structures are disposed, and the plurality of light transmitting structures are disposed in the plurality of opening regions in one-to-one correspondence.

In some embodiments, the display panel further includes a full-display-with-camera region and a conventional display region, wherein the first efficiency enhancement structure and the opening regions are within the full-display-with-camera region.

In some embodiments, the plurality of effective light-emitting regions include a plurality of first effective light-emitting regions disposed in the full-display-with-camera region, and an orthographic projection of each of the plurality of first effective light-emitting regions on the base substrate is circular.

According to some embodiments of the present disclosure, a display panel is provided. The display panel includes a light sensor and the above display panel;
wherein an orthographic projection of the first efficiency enhancement structure of the display panel on the base substrate of the display panel is within an orthographic projection of the light sensor on the base substrate.

### BRIEF DESCRIPTION OF DRAWINGS

For clearer description of the technical solutions according to the embodiments of the present disclosure, the following briefly introduces the accompanying drawings required for describing the embodiments. It is obvious that the accompanying drawings in the following description show merely some embodiments of the present disclosure, and a person of ordinary skill in the art may still derive other drawings from these accompanying drawings without creative efforts.

FIG. 1 is a schematic structural diagram of a display panel according to some embodiments of the present disclosure;

FIG. 2 is a schematic structural diagram of another display panel according to some embodiments of the present disclosure;

FIG. 3 is a schematic structural diagram of a display panel without an efficiency enhancement structure;

FIG. 4 is a schematic structural diagram of another display panel according to some embodiments of the present disclosure;

FIG. 5 is a schematic structural diagram of another display panel according to some embodiments of the present disclosure;

FIG. 6 is a schematic structural diagram of another display panel according to some embodiments of the present disclosure;

FIG. 7 is a schematic structural diagram of another display panel according to some embodiments of the present disclosure;

FIG. 8 is a schematic structural diagram of another display panel according to some embodiments of the present disclosure;

FIG. 9 is a schematic structural diagram of another display panel according to some embodiments of the present disclosure;

FIG. 10 is a schematic structural diagram of a top view of a display panel according to some embodiments of the present disclosure; and

FIG. 11 is a schematic diagram of an enlarged structure of a full-display-with-camera region of the display panel shown in FIG. 10.

Exemplary embodiments of the present disclosure have been shown by the above accompanying drawings, which are described in greater detail later. These accompanying drawings and textual descriptions are not intended to limit in any way the scope of the presently conceived disclosure, but rather to illustrate the concepts of the present disclosure for those skilled in the art by reference to particular embodiments.

### DETAILED DESCRIPTION

To make the objects, technical solutions and advantages of the present disclosure clearer, the embodiments of the present disclosure are further described in detail hereinafter with reference to the accompanying drawings.

The present display panel has some light transmission functions, and light is capable of passing through the display panel from a region between the light-emitting units. However, the light transmission effect of the display panel is poor.

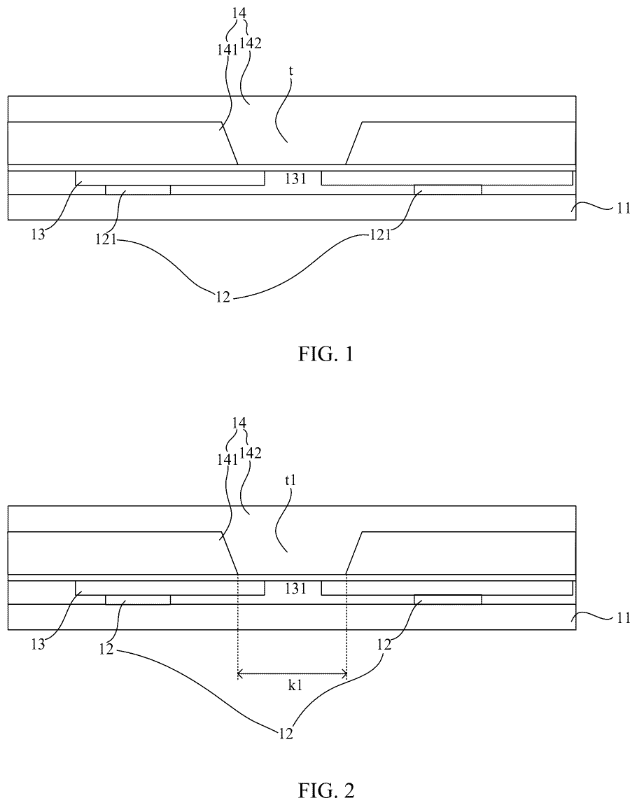

FIG. 1 is a structural schematic diagram of a display panel according to some embodiments of the present disclosure. Thee display panel includes:
a base substrate 11;
a light-emitting layer 12, disposed on the base substrate 11, wherein the light-emitting layer 12 includes a plurality of effective light-emitting regions 121;
a first electrode pattern 13, disposed on the base substrate 11 where the light-emitting layer 12 is disposed, wherein the first electrode pattern 13 includes a plurality of opening regions 131, an orthographic projection of each of the plurality of opening regions 131 on the base substrate 11 is between orthographic projections of the plurality of effective light-emitting regions 121 on the base substrate 11; and
a plurality of first efficiency enhancement structures (EES) 14, disposed on the base substrate 11 where the first electrode pattern 13 is disposed, wherein orthographic projections of the first efficiency enhancement structures 14 on the first electrode pattern 13 is overlapped with the opening regions 131, each of the first efficiency enhancement structures 14 includes a first light transmitting layer 141 and a second light transmitting layer 142, the first light transmitting layer 141 and the second light transmitting layer 142 are sequentially laminated on the base substrate 11 where the first electrode pattern 13 is disposed, a protrusion structure t is disposed on one of the first light transmitting layer 141 and the second light transmitting layer 142 towards the other of the first light transmitting layer and the second light transmitting layer, and a refractive index of the first light transmitting layer 141 is less than a refractive index of the second light transmitting layer 142.

The light can be deflected (e.g., refracted or reflected) at the interface of the first light transmitting layer 141 and the second light transmitting layer 142 to provide control over the direction of the light. The effect of improving the efficiency of the frontal light output can be realized by this control effect.

In summary, embodiments of the present disclosure provide a display panel. The opening regions are disposed on the first electrode pattern of the display panel, and the opening regions are between the effective light-emitting regions, such that the blocking of light by the first electrode pattern is reduced, and the transmittance rate of the display panel is improved. Furthermore, the first efficiency enhancement structure is disposed on the opening regions to improve the frontal light output efficiency, in this way, not only the transmittance rate of the display panel is increased, but also the emission angle of a portion of the light through the display panel is reduced, causing the light through the display panel more concentrated, such that the light transmission effect of the display panel is enhanced.

In addition, in the case that a light sensor is disposed at the back of the display panel, the above first efficiency enhancement structure cooperates with the opening region, such that the amount of light entering the light sensor is increased to improve the operation effect of the light sensor.

It should be noted that although a portion of the light can pass through the display panel at a larger angle, the portion of the light is difficult to be directly observed by the user and the light sensor, and the portion of the light can be called ineffective light. In the display panel according to the embodiments of the present disclosure, the first efficiency enhancement structure can reduce the exit angle of the portion of the light through the display panel, and reduce the proportion of the ineffective light in the overall light. In addition, the opening region also improves the transmittance rate of the display panel, the total amount of light transmitting through the display panel is increased, and thus the opening region can cooperate with the first efficiency enhancement structure to jointly enhance the light transmission effect of the display panel. Correspondingly, the light transmission effect of the display panel involved in the embodiments of the present disclosure refers to the transmittance rate of the display panel and the frontal light output efficiency, and the transmittance rate of the display panel and the frontal light output efficiency are positively correlated with the light transmission effect of the display panel.

In the display panel according to the embodiments of the present disclosure, the first efficiency enhancement structure has a plurality of structures, which are described separately hereinafter.

In a first structure, the protrusion structure includes a first protrusion structure disposed on the second light transmitting layer. As shown in FIG. 2, FIG. 2 is a structural schematic diagram of another display panel according to embodiments of the present disclosure, a first hole k1 is defined in the first light transmitting layer 141, and the orthographic projection of the first hole k1 on the base substrate 11 is overlapped with the orthographic projection of the opening region 131 of the first electrode pattern 13 on the base substrate 11.

The first protrusion structure t1 is disposed on the second light transmitting layer 142 facing the base substrate 11, and the first protrusion structure t1 is filled in the first hole k1.

In this structure, because the refractive index of the first light transmitting layer 141 is less than the refractive index of the second light transmitting layer 142, light irradiated to the hole wall of the first hole k1 is fully reflected at the hole wall. The angle between the fully reflected portion of light and the vertical direction is small, and most of the light is ejected from the display panel at the interface between the display panel and the external environment, and is not fully reflected at the interface. The fully reflected light is mainly directed to the front of the display panel, such that the effect of increasing the front light output efficiency of the display panel can be realized through the first hole k1 and the first protrusion structure t1.

Because the first efficiency enhancement structure 14 is disposed between the effective light-emitting regions 121, the frontal light output efficiency of the region between the effective light-emitting regions 121 is increased. The light transmitting through the region is the light from the outside directed to the display panel, such as light emitted from an outside light source, or light reflected from an outside object. For example, in the case that the light sensor (e.g., a camera, an infrared sensor, or the like) is disposed at the back of the display panel, and the orthographic projection of the first efficiency enhancement structure on the base substrate is within the orthographic projection of the light sensor on the base substrate, the first efficiency enhancement structure 14 causes more light to pass through the display panel and be directed to the light sensor, i.e., the amount of light entering the light sensor is increased to improve the operation effect of the light sensor (e.g., imaging effect).

In the embodiments of the present disclosure, the light-emitting layer 12 includes an electroluminescent material.

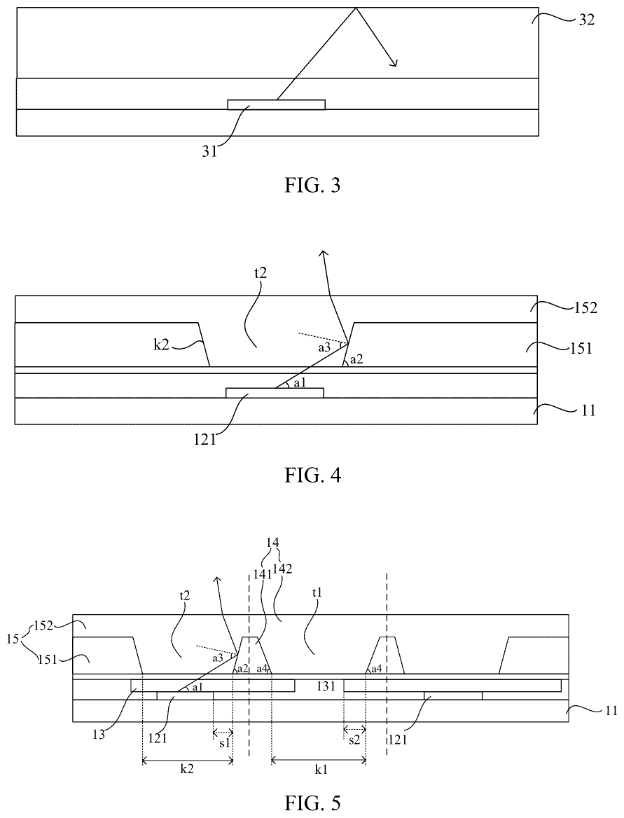

FIG. 3 is a schematic structural diagram of a display panel without an efficiency enhancement structure. The display panel includes a display structure 31 and a cover glass 32 disposed on the display structure. In the case that the light is directed to the cover glass 32, because the refractive index of the cover glass 32 is greater than the refractive index of the air in the external environment, a portion of the light is fully reflected at the interface between the cover glass 32 and the external environment, and the portion of light is not directed out of the display panel. The display panel according to the embodiments of the present disclosure can solve this problem.

FIG. 4 is a schematic structural diagram of another display panel provided according to some embodiments of the application, wherein the display panel further includes a plurality of second efficiency enhancement structures 15. The second efficiency enhancement structures 15 includes a third light transmitting layer 151 and a fourth light transmitting layer 152. The third light transmitting layer 151 and the fourth light transmitting layer 152 are sequentially laminated on the base substrate 11 where the first electrode pattern 13 is disposed.

A second hole k2 is defined in the third light transmitting layer 151 has, an orthographic projection of the second hole k2 on the base substrate 11 is overlapped with the orthographic projection of the effective light-emitting region 121 on the base substrate 11. A second protrusion structure t2 is disposed on the fourth light transmitting layer 152 towards the third light transmitting layer, and the second protrusion structure t2 is filled in the second hole k2. The dimension of second hole k2 increases in a direction away from the base substrate 11 (the upward direction in FIG. 4), such that the light is reflected towards the outside of the display panel.

The second efficiency enhancement structure 15, disposed on the effective light-emitting region 121, improves the frontal light output efficiency of the light emitted from the effective light-emitting region 121, and ensures that the picture perceived by the user on the front side of the display panel is brighter, thereby improving the user experience and reducing the power consumption of the display panel.

The angle between the light emitted from the effective light-emitting region 121 and the horizontal plane is a1, the slope angle of the hole wall of the second hole is a2, the incident angle of the light emitted from the effective light-emitting region 121 at the hole wall of the second hole k2 is a3, and a3+a2−a1=90°.

The refractive index of the third light transmitting layer 151 is n1, and the refractive index of the fourth light transmitting layer 152 is n2. The total reflection occurs in the case that the incident angle a3>arc sin(n1/n2). Exemplarily, taking the refractive index n1=1.47 and n2−1.7 as an example, a3 is about 60°, assuming that a1 is 30° (light less than this angle is less useful for the display), and a2 is about 60°. Taking into account the influence of the process and the light output efficiency, the slope angle of the hole wall of the second hole ranges from a2−20° to a2+20°.

FIG. 5 is a schematic structural diagram of another display panel according to some embodiments of the present disclosure. The dimension of the first hole k1 increases in a direction away from the base substrate 11, and the slope angle a4 of the hole wall of the first hole k1 is less than the slope angle a2 of the hole wall of the second hole k2 described above, i.e., the hole wall of the first hole k1 is more inclined. In this structure, the hole wall of the first hole k1 can receive more external light and reflect the light towards the interior of the display panel, and can also reflect more light from the interior of the display panel out of the display panel.

Optionally, the orthographic projection of the effective light-emitting region 121 on the base substrate 11 is within the orthographic projection of the second hole on the base substrate, and a first distance s1 is defined between the edge of the orthographic projection of the effective light-emitting region 121 on the base substrate 11 and the edge of the orthographic projection of the second hole k2 on the base substrate 11.

The orthographic projection of the opening region 131 of the first electrode pattern 13 on the base substrate 11 is within the orthographic projection of the first hole k1 on the base substrate, and a second distance s2 is defined between the edge of the orthographic projection of the opening region on the base substrate and the edge of the orthographic projection of the first hole k1 on the base substrate 11, wherein the second distance s2 is greater than the first distance s1. The first distance s1 is less than 5 μm, such as 4 μm, 2 μm, or 1 μm, or the like.

In this structure, compared to the distance between the second hole k2 above the effective light-emitting region 121 and the effective light-emitting region 121, the distance between the first hole k1 over the opening region 131 and the opening region 131 is larger, such that more light can pass through the display panel through the first hole k1, and the transmittance rate of the display panel is improved.

In an exemplary embodiment, the first light transmitting layers 141 of the plurality of first efficiency enhancement structures 14 are disposed in a same layer, and the second light transmitting layers 142 of the plurality of first efficiency enhancement structures 14 are disposed in a same layer. In this way, the film layer structure is simplified, the composition process and the manufacturing process is saved, and the manufacturing speed of the display panel is improved.

The first light transmitting layer 141 and the third light transmitting layer 151 are disposed in a same layer, and the second light transmitting layer 142 and the fourth light transmitting layer 152 are disposed in a same layer. This structure can also simplify the film layer structure, save the composition process and the manufacturing process, and improve the manufacturing speed of the display panel. In this structure, the plurality of first efficiency enhancement structures 14 and the plurality of second efficiency enhancement structures 15 on the display panel are only formed by two film layers, one film layer includes the first light transmitting layer 141 and the third light transmitting layer 151, and the other film layer includes the second light transmitting layer 142 and the fourth light transmitting layer 152. The first light transmitting layer 141, the third light transmitting layer 151, the second light transmitting layer 142, and the fourth light transmitting layer 152 are all composed of a light transmissive material.

It should be noted that the first efficiency enhancement structure 14 and the second efficiency enhancement structure 15 shown in FIG. 5 are adjacent and connected to each other, which is not limited in the embodiments of the present disclosure. For example, the first efficiency enhancement structure 14 and the second efficiency enhancement structure 15 are not adjacent and connected, which is not limited in the embodiments of the present disclosure.

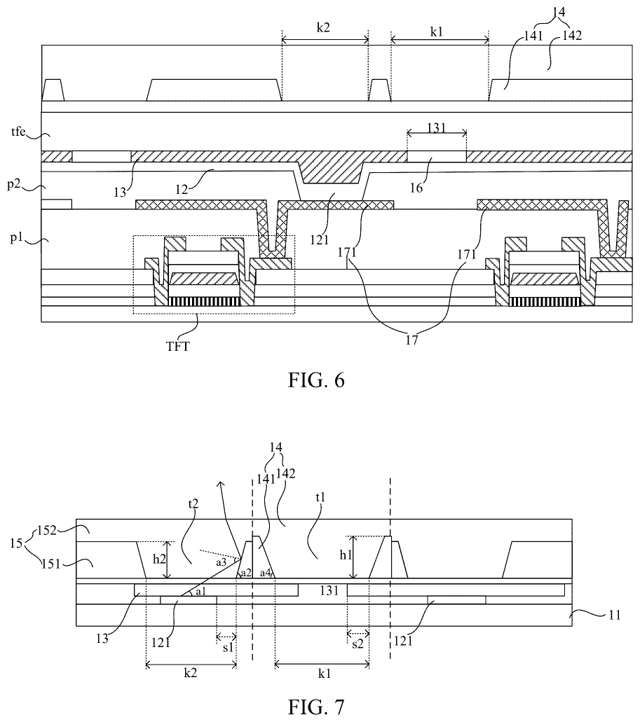

FIG. 6 is a structural schematic diagram of another display panel according to some embodiments of the present disclosure, wherein the first electrode pattern 13 is a cathode pattern.

The display panel includes a plurality of light transmitting structures 16, the light transmitting structures 16 are disposed on the base substrate 11 provided with a light-emitting layer 12, and the material of the light transmitting structures 16 includes a cathode patterning material (CPM). The CPM is a material that is not adhered to the material of the cathode pattern, and in the case that the light-transmissive structure 16 made of the CPM is formed, when the cathode pattern is formed by the evaporation-deposition process, the region where the light-transmissive structure 16 is disposed naturally forms the opening region 131. Therefore, the first electrode pattern 13 is disposed on the base substrate 11 where the plurality of light-transmissive structures 16 are disposed, and the plurality of light-transmissive structures 16 are disposed in the plurality of opening regions 131 in one-to-one correspondence.

Exemplarily, the material of the cathode pattern includes magnesium (Mg), silver (Ag), or the like, and the cathode patterning material includes a fluorine-containing organic substance.

Optionally, the display panel further includes a second electrode pattern 17, the second electrode pattern 17 is disposed between the base substrate 11 and the light-emitting layer 12 (which indicates that the second electrode pattern 17 is disposed between the base substrate 11 and the light-emitting layer 12 in a direction perpendicular to the base substrate 11), the second electrode pattern 17 includes a plurality of second electrodes 171, and the orthographic projection of the opening region 131 on the second electrode pattern 17 is between the plurality of second electrodes 171. That is, other electrode patterns in the display panel also avoid the opening region 131 to avoid obscuring the opening region 131, such that the transmittance rate of the display panel is improved. The second electrode 171 is an anode. The region in the light-emitting layer 12 that is in contact with the first electrode pattern 12 and the second electrode 171 is the effective light-emitting region 121, the first electrode pattern 12, the effective light-emitting region 121 of the light-emitting layer, and the second electrode 171 constitute a light-emitting unit, and the light-emitting unit is an organic light-emitting diode (OLED).

Optionally, the display panel further includes a plurality of thin film transistors TFT, the plurality of thin film transistors TFT are disposed between the second electrode pattern 17 and the base substrate 11, and the orthographic projection of each of the plurality of opening regions 131 on the base substrate 11 is between the orthographic projections of the plurality of thin film transistors TFT on the base substrate 11. That is, the thin film transistors TFT can avoid the opening region 131. Because the thin film transistors TFT include electrodes, active layers and other structures with low transmittance, the thin film transistors TFT can avoid the thin film transistors TFT from blocking the opening regions 131, such that the transmittance of the display panel is improved. The thin film transistors TFT are electrically connected to the second electrode 171 (e.g., the thin film transistors TFT include a gate, a source, and a drain, and the drain is electrically connected to the second electrode 171) for controlling the switching on and switching off of the above light-emitting unit.

In addition, the display panel further includes a first overcoat layer p1, a second overcoat layer p2, and a thin film encapsulation layer tfe, wherein the first overcoat layer p1 is disposed between the thin film transistor TFT and the second electrode pattern 17, the second overcoat layer p2 is disposed between the second electrode pattern 17 and the light-emitting layer 12, and the thin film encapsulation layer tfe is disposed between the first electrode pattern 13 and the first efficiency enhancement structure 14.

FIG. 7 is a schematic structural diagram of another display panel according to some embodiments of the present disclosure. The thickness hl of the third light transmitting layer 151 is greater than the thickness h2 of the first light transmitting layer 141. In this structure, the depth of the first hole k1 disposed on the first light transmitting layer 141 is greater than the depth of the second hole k2 above the light-emitting device 12, and the area of the hole wall of the first hole k1 is increased, such that this first hole wall of the first hole k1 can receive more light and reflect the light to enhance the contribution of the first efficiency enhancement structure 14 to the frontal light output efficiency.

It should be noted that the first efficiency enhancement structure 14 and the second efficiency enhancement structure 15 shown in FIG. 7 are adjacent and connected to each other, which is not limited in the embodiments of the present disclosure. For example, the first efficiency enhancement structure 14 and the second efficiency enhancement structure 15 are not adjacent and connected, which is not limited in the embodiments of the present disclosure.

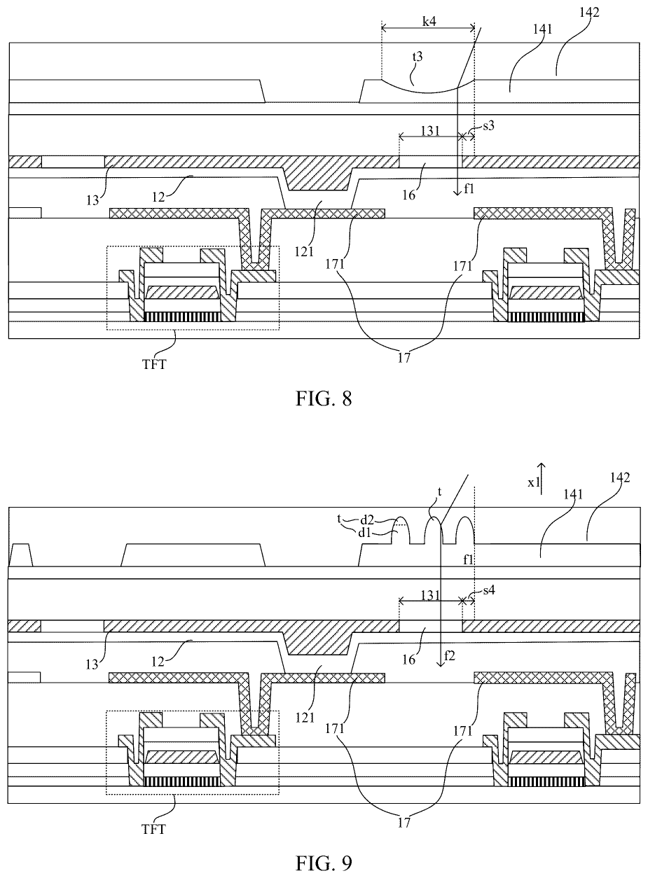

In the second structure, referring to FIG. 8, FIG. 8 is a structural schematic diagram of another display panel according to some embodiments of the present disclosure. A recess k4 is defined in the first light transmitting layer 141, and an orthographic projection of the recess k4 on the base substrate 11 is overlapped with the orthographic projection of the opening region 131 of the first electrode pattern 13 on the base substrate 11. A third protrusion structure t3 is disposed on the second light transmitting layer 141 towards the second light transmitting layer, and the third protrusion structure t3 is filled in the recess k4. The intersection interface between the recess k4 and the third protrusion structure t3 also reduces the incident angle of the light ray f1 (the incident angle is the angle between the light ray directed to the interior of the display panel through the intersection interface and the vertical direction) to improve the efficiency of the frontal light output of the display panel. In addition, similar to the structure shown in FIG. 5, a third distance s3 is defined between the edge of the orthographic projection of the recess k4 on the base substrate 11 and the edge of the orthographic projection of the opening region 131 on the base substrate 11 may be (exemplarily, the third distance s3 is greater than 0 and less than 6μm), and the third distance s3 is also greater than the first distance s1 in FIG. 5.

Optionally, the orthographic projection of the opening region 131 of the first electrode pattern 13 on the base substrate 11 is within the orthographic projection of the pit k4 on the base substrate 11. This structure can enhance the coverage of the recess k4, such that the recess k4 can process more light and further improve the frontal light output efficiency.

The recess k4 is an arc-shaped recess, and the center of the arc-shaped recess k4 is outside of the recess k4. That is, the recess k4 is a gentle arc shape to improve the enhancement effect of the recess k4 for the frontal light output efficiency.

In the third structure, referring to FIG. 9, FIG. 9 is a structural schematic diagram of another display panel according to some embodiments of the present disclosure. The first light transmitting layer 141 is provided with at least two protrusion structures t. The interface between the protrusion structures t and the second light transmitting layer 142 also reduce the incident angle of the light ray f2 to improve the frontal light emission efficiency of the display panel.

Optionally, the protrusion structure t includes a base d1 and an arc-shaped protrusion d2 disposed on the base d1, a center z of the arc-shaped protrusion d2 is disposed on a side, away from the substrate 11, of the center of the protrusion structure t, and the center z of the protrusion structure t is the center of the protrusion structure t in a direction x1 perpendicular to the base substrate 11. In this structure, the protrusion structure t protrudes more from the other regions of the first light transmitting layer 141, such that the enhancement effect of the protrusion structure t on the frontal light output efficiency is improved.

In addition, the protrusion structure t has other shapes, such as an elliptical shape, or the like, which is not limited in the embodiments of the present disclosure.

Furthermore, similar to the structure shown in FIG. 5, a fourth distance s4 is defined between the edges of the orthographic projection of the plurality of protrusion structures t on the base substrate 11 and the edges of the orthographic projection of the opening region 131 on the base substrate 11, and the fourth distance s4 is also greater than the first distance s1 in the above FIG. 5.

The above embodiments provide a plurality of first efficiency enhancement structures with different structures, and the plurality of first efficiency enhancement structures in the display panel according to the embodiments of the present disclosure includes at least one of the first efficiency enhancement structures of the above plurality of first efficiency enhancement structures.

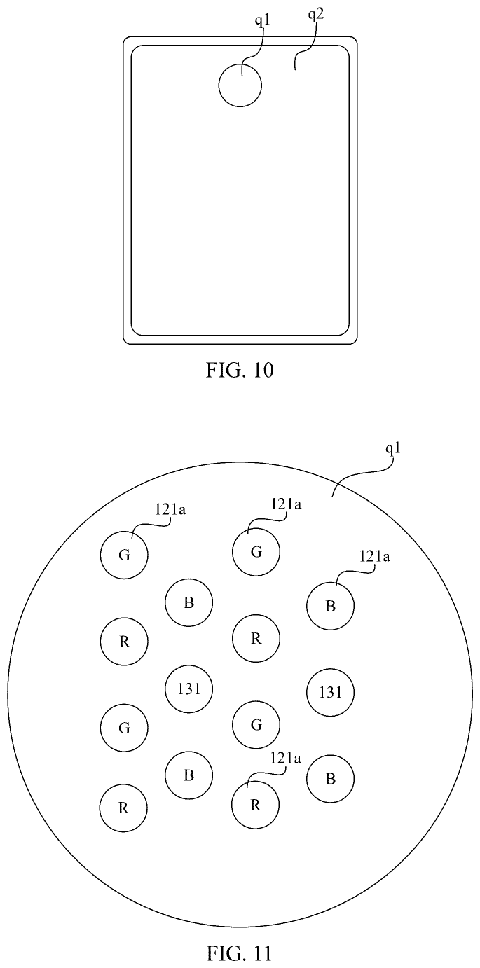

FIG. 10 is a structural schematic diagram of a top view of a display panel according to some embodiments of the present disclosure, wherein the display panel includes a full-display-with-camera (FDC) region q1 and a conventional display region q2, and the first efficiency enhancement structure according to the above embodiment and the opening region of the first electrode pattern are within the full-display-with-camera region q1. The full-display-with-camera region q1 is a region having a light transmission function, and a light sensor (such as a camera or an infrared sensor, or the like) is provided below the full-display-with-camera region q1 in the case that the display panel is applied in a display device. Because the first efficiency enhancement structure according to the above embodiments and the opening region on the first electrode pattern are within the full-display-with-camera region q1, the transmittance rate of the full-display-with-camera region q1 and the frontal light output efficiency are improved, such that the amount of light that can be directed to the light sensor through the full-display-with-camera region q1 is increased, and the light is directed to the light sensor at a small incident angle, and the operation effect of the light sensor is improved.

In addition, the second efficiency enhancement structure according to the above embodiments disposed on the effective light-emitting region is also within at least one of the full-display-with-camera region q1 and the conventional display region q2.

FIG. 11 is an enlarged schematic structural diagram of the full-display-with-camera region of the display panel shown in FIG. 10, wherein the plurality of effective light-emitting regions 121 includes a plurality of first effective light-emitting regions 121a within the full-display-with-camera region q1, and an orthographic projection of each of the plurality of first effective light-emitting regions 121a on the base substrate is circular. The circular first effective light-emitting regions 121a can improve the transmittance rate of the full-display-with-camera region q1, thereby improve the light transmission effect of the full-display-with-camera region q1. In addition, the effective light-emitting region within the conventional display region q2 is also circular, which is not limited in the embodiments of the present disclosure.

In addition, the shape of the opening region 131 in the first electrode pattern is circular, elliptical (circular and elliptical opening region 131 can improve the transmittance of the full-display-with-camera region q1) or other shapes, which is not repeated in the embodiments of the present disclosure.

The first effective light-emitting region 121a includes a red effective light-emitting region R, a green effective light-emitting region G, and a blue effective light-emitting region B. The distances between the opening region 131 of the first electrode pattern and the different effective light-emitting regions are the same or different, which is not limited in the embodiments of the present disclosure.

In an exemplary embodiment, the first efficiency enhancement structure according to the above embodiments and the opening region of the first electrode pattern are also within the full-display-with-camera region q1 and the conventional display region q2. In this structure, the display panel is a display panel with a transparent function.

In summary, embodiments of the present disclosure provide a display panel. An opening region is disposed on a first electrode pattern of the display panel, and the opening region is between the effective light-emitting regions, such that the blocking of light by the first electrode pattern is reduced, and the transmittance rate of the display panel is improved. Furthermore, a first efficiency enhancement structure is disposed on the opening region to improve the frontal light output efficiency, in this way, not only the transmittance rate of the display panel is increased, but also the emission angle of a portion of the light through the display panel is reduced, causing the light through the display panel more concentrated, such that the light transmission effect of the display panel is enhanced

In addition, in the case that a light sensor is disposed at the back of the display panel, the above first efficiency enhancement structure cooperates with the opening region, such that the amount of light entering the light sensor is increased to improve the operation effect of the light sensor.

Embodiments of the present disclosure also provide a display device, and the display device includes the light sensor and any of the display panels according to the above embodiments.

The orthographic projection of the first efficiency enhancement structure of the display panel on the base substrate of the display panel is within an orthographic projection of the light sensor on the base substrate.

In an exemplary embodiment, the display panel has a full-display-with-camera region and a conventional display region, and the orthographic projection of the light sensor on the display panel is overlapped with the full-display-with-camera region. The full-display-with-camera region is a region with a light transmission function, such that the light sensor can obtain light outside the display device through the full-display-with-camera region.

In summary, embodiments of the present disclosure provide a display device. The display device includes a light sensor and a display panel, an opening region is disposed on a first electrode pattern of the display panel, and the opening region is between the effective light-emitting regions, such that the blocking of light by the first electrode pattern is reduced, and the transmittance rate of the display panel is improved. Furthermore, a first efficiency enhancement structure is disposed on the opening region to improve the frontal light output efficiency, in this way, not only the transmittance rate of the display panel is increased, but also the emission angle of a portion of the light through the display panel is reduced, causing the light through the display panel more concentrated, such that the light transmission effect of the display panel is enhanced, the amount of light entering the light sensor is increased, and the operation effect of the light sensor is improved.

The term “at least one of A or B” in the present application is merely a description of an association relationship of an associated object, indicating that three relationships exist. For example, at least one of A and B is represented as these three cases: only A is present, A and B are present, and only B is present. Similarly, “at least one of A, B, or C” indicates that seven relationships exist, and can be expressed as these seven cases: only A is present, only B is present, only C is present, A and B are present, A and C are present, C and B are present, and A, B, and C are present. Similarly, “at least one of A, B, C or D” indicates that fifteen relationships exist, and can be expressed as these fifteen cases: only A is present, only B is present, only C is present, only D is present, A and B are present, A and C are present, A and D are present, C and B are present, D and B are present, C and D are present, both D and C are present, A, B and C are present, A, B and D are present, A, C and D are present, B, C and D are present, and A, B, C and D are present.

It is to be noted that in the accompanying drawings, the dimensions of the layers and regions may be exaggerated for the clarity of illustration. And it should be understood that when an element or layer is referred to as being “on” another element or layer, it may be directly on the other element or an intermediate layer may be present. In addition, it should be understood that when the element or layer is referred to as being “under” another element or layer, it can be directly under the other element, or more than one intermediate layer or element can be present. It should also be understood that when a layer or element is referred to as being “between” two layers or elements, it may be the only layer between the two layers or elements, or more than one intermediate layer or element may also be present. Similar reference marks throughout indicate similar elements.

In the application, the terms “first,” “second,” “third,” “fourth,” and “fifth” are used for descriptive purposes only and are not to be construed as indicating or implying relative importance. The term “plurality” refers to two or more, unless otherwise expressly limited.

The foregoing are only optional embodiments of the present disclosure and are not intended to limit the application, and any modifications, equivalent substitutions, improvements, etc., within the spirit and principles of the present disclosure shall be included in the scope of protection of the present disclosure.

1. A display panel, comprising:
a base substrate;
a light-emitting layer, disposed on the base substrate, wherein the light-emitting layer comprises a plurality of effective light-emitting regions;
a first electrode pattern, disposed on the base substrate where the light-emitting layer is disposed, wherein the first electrode pattern comprises a plurality of opening regions, an orthographic projection of each of the plurality of opening regions on the base substrate being between orthographic projections of the plurality of effective light-emitting regions on the base substrate; and
a plurality of first efficiency enhancement structures, disposed on the base substrate where the first electrode pattern is disposed, wherein orthographic projections of the plurality of first efficiency enhancement structures on the first electrode pattern are overlapped with the opening regions, each of the plurality of first efficiency enhancement structures comprises a first light transmitting layer and a second light transmitting layer;
wherein the first light transmitting layer and the second light transmitting layer are sequentially laminated on the base substrate where the first electrode pattern is disposed, a protrusion structure is disposed on one of the first light transmitting layer and the second light transmitting layer towards the other of the first light transmitting layer and the second light transmitting layer, and a refractive index of the first light transmitting layer is less than a refractive index of the second light transmitting layer.

2. The display panel according to claim 1, further comprising: a second electrode pattern, disposed between the base substrate and the light-emitting layer, wherein the second electrode pattern comprises a plurality of second electrodes, wherein orthographic projections of the plurality of opening regions on the second electrode pattern are between the plurality of second electrodes.

3. The display panel according to claim 2, further comprising: a plurality of thin film transistors, disposed between the second electrode pattern and the base substrate, wherein the orthographic projections of the plurality of opening regions on the base substrate are between orthographic projections of the plurality of thin film transistors on the base substrate.

4. The display panel according to claim 1, wherein
a first hole is defined in the first light transmitting layer, wherein an orthographic projection of the first hole on the base substrate is overlapped with the orthographic projection of each of the plurality of opening regions of the first electrode pattern on the base substrate; and
a first protrusion structure is disposed on the second light transmitting layer towards the base substrate, wherein the first protrusion structure is filled in the first hole.

5. The display panel according to claim 4, further comprising: a plurality of second efficiency enhancement structures, wherein each of the plurality of second efficiency enhancement structures comprises a third light transmitting layer and a fourth light transmitting layer; wherein
the third light transmitting layer and the fourth light transmitting layer are sequentially laminated on the base substrate where the first electrode pattern is disposed;
a second hole is defined in the third light transmitting layer, wherein an orthographic projection of the second hole on the base substrate is overlapped with the orthographic projection of each of the plurality of effective light-emitting regions on the base substrate; and a second protrusion structure is disposed on the fourth light transmitting layer towards the third light transmitting layer, wherein the second protrusion structure is filled in the second hole.

6. The display panel according to claim 5, wherein dimensions of the second hole and the first hole both increase in a direction away from the base substrate, and a slope angle of a hole wall of the first hole is greater than a slope angle of a hole wall of the second hole.

7. The display panel according to claim 5, wherein
the orthographic projection of the effective light-emitting regions on the base substrate is within the orthographic projection of the second hole on the base substrate, and a first distance is defined between an edge of the orthographic projection of the effective light-emitting region on the base substrate and an edge of the orthographic projection of the second hole on the base substrate; and
the orthographic projection of the opening region of the first electrode pattern on the base substrate is within the orthographic projection of the first hole on the base substrate, and a second distance is defined between an edge of the orthographic projection of the opening region on the base substrate and an edge of the orthographic projection of the first hole on the base substrate, and the second distance is greater than the first distance.

8. The display panel according to claim 5, wherein a thickness of the third light transmitting layer is greater than a thickness of the first light transmitting layer.

9. The display panel according to claim 5, wherein
the first light transmitting layers in the plurality of first efficiency enhancement structures are disposed in a same layer, and the second light transmitting layers in the plurality of first efficiency enhancement structures are disposed in a same layer; and
the first light transmitting layer and the third light transmitting layer are disposed in a same layer, and the second light transmitting layer and the fourth light transmitting layer are disposed in a same layer.

10. The display panel according to claim 1, wherein
a recess is defined in the first light transmitting layer, wherein an orthographic projection of the recess on the base substrate is overlapped with the orthographic projection of the opening region of the first electrode pattern on the base substrate; and
a third protrusion structure is disposed on the second light transmitting layer towards the second light transmitting layer, wherein the third protrusion structure is filled in the recess.

11. The display panel according to claim 10, wherein the orthographic projection of the opening region of the first electrode pattern on the base substrate is within an orthographic projection of the recess on the base substrate.

12. The display panel according to claim 10, wherein the recess is an arc-shaped recess and a center of the arc-shaped recess is outside the recess.

13. The display panel according to claim 1, wherein at least two protrusion structures are disposed on the first light transmitting layer.

14. The display panel according to claim 13, wherein the protrusion structure comprises a base and an arc-shaped protrusion disposed on the base, a center of the arc-shaped protrusion is disposed on a side, away from the base substrate, of a center of the each of the protrusion structures, and the center of the protrusion structure is a center of the protrusion structure in a direction perpendicular to the base substrate.

15. The display panel according to claim 1, wherein
the first electrode pattern is a cathode pattern; and
the display panel comprises a plurality of light transmitting structures disposed on the base substrate provided with the light-emitting layer, wherein a material of each of the plurality of light transmitting structures comprises a cathode patterning material; and
the first electrode pattern is disposed on the base substrate where the plurality of light transmitting structures are disposed, and the plurality of light transmitting structures are disposed in the plurality of opening regions in one-to-one correspondence.

16. The display panel according to claim 1, further comprising: a full-display-with-camera region and a conventional display region, wherein the first efficiency enhancement structure and the opening regions are within the full-display-with-camera region.

17. The display panel according to claim 16, wherein the plurality of effective light-emitting regions comprise a plurality of first effective light-emitting regions disposed in the full-display-with-camera region, and an orthographic projection of each of the plurality of first effective light-emitting regions on the base substrate is circular.

18. A display device, comprising: a light sensor and a display panel; wherein
the display panel comprises:
a base substrate;
a light-emitting layer, disposed on the base substrate, wherein the light-emitting layer comprises a plurality of effective light-emitting regions;
a first electrode pattern, disposed on the base substrate where the light-emitting layer is disposed, wherein the first electrode pattern comprises a plurality of opening regions, an orthographic projection of each of the plurality of opening regions on the base substrate being between orthographic projections of the plurality of effective light-emitting regions on the base substrate; and
a plurality of first efficiency enhancement structures, disposed on the base substrate where the first electrode pattern is disposed, wherein orthographic projections of the plurality of first efficiency enhancement structures on the first electrode pattern are overlapped with the opening regions, each of the plurality of first efficiency enhancement structures comprises a first light transmitting layer and a second light transmitting layer;
wherein the first light transmitting layer and the second light transmitting layer are sequentially laminated on the base substrate where the first electrode pattern is disposed, a protrusion structure is disposed on one of the first light transmitting layer and the second light transmitting layer towards the other of the first light transmitting layer and the second light transmitting layer, and a refractive index of the first light transmitting layer is less than a refractive index of the second light transmitting layer; and
an orthographic projection of the first efficiency enhancement structure of the display panel on the base substrate of the display panel is within an orthographic projection of the light sensor on the base substrate.

19. The display device according to claim 18, wherein the display panel further comprises: a second electrode pattern, disposed between the base substrate and the light-emitting layer, wherein the second electrode pattern comprises a plurality of second electrodes, wherein orthographic projections of the plurality of opening regions on the second electrode pattern are between the plurality of second electrodes.

20. The display device according to claim 19, wherein the display panel further comprises: a plurality of thin film transistors, disposed between the second electrode pattern and the base substrate, wherein the orthographic projections of the plurality of opening regions on the base substrate are between orthographic projections of the plurality of thin film transistors on the base substrate.
